(19) United States
(12) Patent Application Publication
(10) Pub. No.: US 2025/0262964 A1
(43) Pub. Date: Aug. 21, 2025

(54) CHARGING MONITORING APPARATUS, CHARGING MONITORING METHOD, AND CHARGING MONITORING SYSTEM

(71) Applicant: HONDA MOTOR CO., LTD., Tokyo (JP)

(72) Inventors: Kazuhiro Daido, Tokyo (JP); Hirohito Matsubara, Tokyo (JP); Takashi Furukawa, Tokyo (JP); Teruhiko Asahi, Tokyo (JP)

(21) Appl. No.: 19/010,338

(22) Filed: Jan. 6, 2025

(30) Foreign Application Priority Data
Feb. 15, 2024 (JP) 2024-021420

(51) Int. Cl. B60L 53/30; B60L 53/62; B60L 53/66

(52) U.S. Cl. CPC B60L 53/305; B60L 53/62; B60L 53/66; B60L 2250/16

(57) ABSTRACT

A monitoring unit that monitors a state of a charging operation from a power supply device external to a vehicle to a secondary battery included in the vehicle, an identifying unit that detects and identifies a person around the vehicle, and a transmission control unit that controls an operation of an external display device, the external display device being a display device provided in the vehicle at a position viewable from outside of the vehicle are included. The transmission control unit displays on the external display device a notification screen toward a person around the vehicle when the charging operation from the power supply device to the secondary battery is in progress and when it is detected that a person who is different from a current user, who is currently using the vehicle, is present around the vehicle.

### INCORPORATION BY REFERENCE

The present application claims priority under 35 U.S.C. § 119 to Japanese Patent Application No. 2024-021420 filed on Feb. 15, 2024. The content of the application is incorporated herein by reference in its entirety.

### BACKGROUND OF THE INVENTION

### Field of the Invention

The present invention relates to a charging monitoring apparatus, a charging monitoring method, and a charging monitoring system.

### Description of the Related Art

In recent years, in order for more people to have access to reasonable, reliable, sustainable and advanced energy, researches and developments have been conducted regarding power charging/feeding in a mobility having a secondary battery thereon, which are beneficial for efficient energy use.

Japanese Patent Laid-Open No. 2013-21914 discloses a charging monitoring and notifying system that monitors a charging operation to an electric vehicle by a charging system and, when an interruption of the charging operation is detected, transmits a notification message to a person involved in accordance with a series of notification instructions. The notification instructions may include criterion or the like for determining whether the interruption of the charging operation is approved or not and, in accordance with the determination result, transmission of a notification message is not requested.

In the meantime, in a technology relating to power charging/feeding in a mobility having a secondary battery thereon, a challenge is to sequentially and smoothly perform charging from a power supply device to a plurality of vehicles. For example, while a certain power supply device is being used to charge one vehicle, another party who intends to charge another vehicle may be waiting for completion of the charging to the one vehicle. Furthermore, since charging to a vehicle requires substantial time, the user of the one vehicle may leave the one vehicle for little shopping or the like or may take a nap within the one vehicle until completion of the charging. In this case, when the charging to the vehicle completes before the user comes back to the one vehicle or when the user does not notice the completion of charging, the other party who intends to charge the other vehicle may waste time without the power supply device in operation.

To solve the above problem, an object of the present application is to smoothly perform sequential charging from a power supply device to a plurality of vehicles by notifying information such as a state of charging of a vehicle as needed to a person who is waiting for completion of the charging around the vehicle being charged. It consequently contributes to efficient energy use.

### SUMMARY OF THE INVENTION

One aspect of the present invention is a charging monitoring apparatus, comprising a monitoring unit that monitors a state of a charging operation from a power supply device external to a vehicle to a secondary battery included in the vehicle, an identifying unit that detects and identifies a person around the vehicle, and a transmission control unit that controls an operation of an external display device, the external display device being a display device provided in the vehicle at a position viewable from outside of the vehicle, wherein the transmission control unit displays on the external display device a notification screen toward a person around the vehicle when the charging operation from the power supply device to the secondary battery is in progress and when it is detected that a person who is different from a current user, who is currently using the vehicle, is present around the vehicle.

According to another aspect of the present invention, when a person different from the current user stays around the vehicle for a predetermined time defined in advance or longer, the transmission control unit displays the notification screen on the external display device.

According to another aspect of the present invention, the notification screen includes information regarding a charging operation from the power supply device to the secondary battery.

According to another aspect of the present invention, the transmission control unit acquires an input from an external input device provided in the vehicle, the external input device being operable by a person outside the vehicle, the transmission control unit displays on the external display device a message that inquires about necessity of a notification to a passenger of the vehicle when a charging operation from the power supply device to the secondary battery has a predetermined state defined in advance and, when a notification request is input via the external input device, transmits an input notification that the notification request is input to a user terminal device, the notification request being a request for the notification to a passenger of the vehicle, the user terminal device being defined in advance and being accessible by the current user.

According to another aspect of the present invention, when a charging operation from the power supply device to the secondary battery does not have the predetermined state, the transmission control unit displays on the external display device an expected time until the charging operation reaches the predetermined state or a current residual capacity of the vehicle.

According to another aspect of the present invention, when the notification request is input via the external input device and when a passenger is detected inside the vehicle, the transmission control unit notifies the passenger that there is a person waiting around the vehicle through an output device provided inside the vehicle.

According to another aspect of the present invention, the identifying unit identifies a person inside the vehicle, and, when the notification request is input via the external input device and when the current user of the vehicle is detected inside the vehicle, the transmission control unit notifies the current user that there is a person waiting around the vehicle through an output device provided inside the vehicle.

According to another aspect of the present invention, when the notification request is input via the external input device and when the current user is not detected inside the vehicle, the transmission control unit transmits a notification that there is a person waiting around the vehicle to a user terminal device, the user terminal device being defined in advance and being accessible by the current user.

According to another aspect of the present invention, the vehicle includes an external microphone that acquires voice of a person present outside the vehicle and an external speaker that outputs voice to outside of the vehicle, and, when the notification request is input via the external input device and when the current user is not detected inside the vehicle, the transmission control unit establishes communication with a predefined user terminal device owned by the current user for allowing talking by employing the external microphone and the external speaker.

According to another aspect of the present invention, the transmission control unit acquires an expected arrival time of the current user to a charging location for the vehicle, the expected arrival time being input to the user terminal device by the current user, and displays the acquired expected arrival time on the external display device.

According to another aspect of the present invention, the user terminal device is a mobile terminal carried by the current user, and the transmission control unit calculates an expected arrival time when the current user arrives at the vehicle based on positional information on a current position of the current user transmitted by the user terminal device and a current position of the vehicle and displays the calculated expected arrival time on the external display device.

According to another aspect of the present invention, the predetermined state is a state acquired by charging the secondary battery until the residual capacity of the secondary battery reaches a predefined target value and finishing the charging operation and/or a state acquired by interrupting the charging operation of the secondary battery before the residual capacity of the secondary battery reaches the target value.

Another aspect of the present invention is a charging monitoring system, comprising the charging monitoring apparatus according to any one of the above and an autonomous driving apparatus being mounted in the vehicle and causing the vehicle to run to a destination by autonomous driving, wherein the transmission control unit in the charging monitoring apparatus communicates with a predefined user terminal device being accessible by the current user, and the autonomous driving apparatus causes the vehicle to run to a predetermined destination defined in advance by autonomous driving and causes the vehicle to be parked at the destination when the transmission control unit receives an allowance notification for autonomous driving from the user terminal device.

A still another aspect of the present invention is a charging monitoring method executed by a computer in a charging monitoring apparatus that monitors a charging operation from a power supply device external to a vehicle to a secondary battery included in the vehicle, the method comprising a monitoring step of monitoring a state of a charging operation from the power supply device to the secondary battery, an identifying step of detecting and identifying a person around the vehicle, and a transmitting step of controlling an operation of an external display device, the external display device being a display device provided in the vehicle at a position viewable from outside of the vehicle, wherein the transmitting step displays on the external display device a notification screen toward a person around the vehicle when the charging operation from the power supply device to the secondary battery is in progress and when it is detected that a person who is different from a current user, who is currently using the vehicle, is present around the vehicle.

According to aspects of the present invention, sequential charging from a power supply device to a plurality of vehicles can be performed smoothly by notifying information such as a state of charging of a vehicle as needed to a person who is waiting for completion of the charging around the vehicle being charged.

### BRIEF DESCRIPTION OF THE DRAWINGS

FIG. 1 is a diagram showing an example of a scene where a vehicle including a charging monitoring apparatus is employed according to one embodiment of the present invention;

FIG. 2 is a diagram showing a configuration of an interior of a charging opening of the vehicle;

FIG. 3 is a diagram showing a configuration of the charging monitoring apparatus;

FIG. 4 shows an example of a notification screen including a message that is displayed on an external touch panel and that inquires about necessity of a notification to a passenger of the vehicle; and

FIG. 5 is a flowchart showing a procedure of an operation in the charging monitoring apparatus.

### DETAILED DESCRIPTION OF THE INVENTION

Embodiments of the present invention are described below with reference to drawings.

### 1. Embodiment

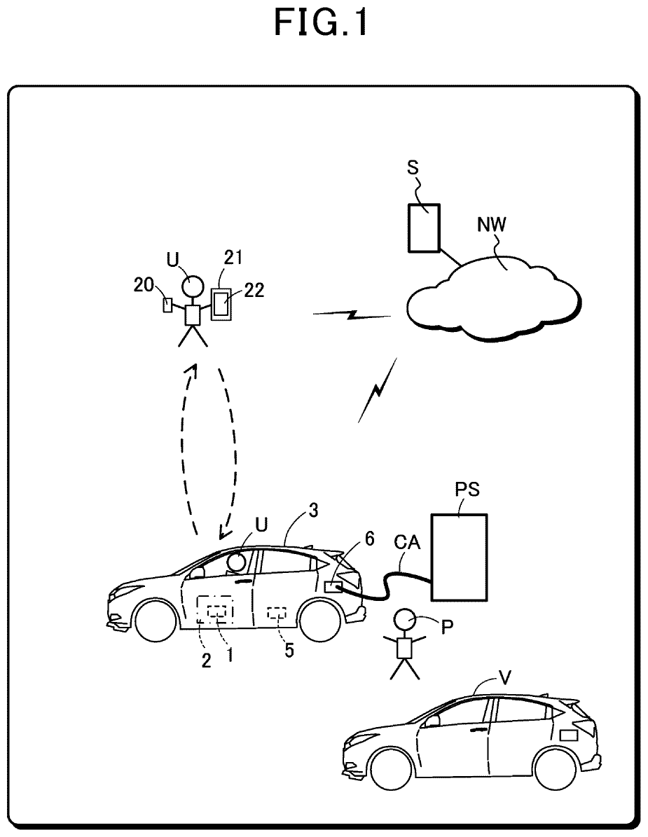

FIG. 1 is a diagram showing an example of a scene where a vehicle 3 including a charging monitoring apparatus 1 and a charging monitoring system 2 including the charging monitoring apparatus 1 is employed according to one embodiment of the present invention. The vehicle 3 is, for example, an electric vehicle and includes a secondary battery 5 that supplies power for vehicle driving. The secondary battery 5 in the vehicle 3 is charged from a power supply device PS external to the vehicle 3. The power supply device PS is an arbitrary power supply device that is installed in an arbitrary charging site and that can perform charging to the vehicle.

It should be noted that the expression “charging the vehicle 3” below refers to charging the secondary battery 5 in the vehicle 3.

The charging monitoring apparatus 1 in this embodiment is included in the vehicle 3 but may be configured as an external apparatus provided externally to the vehicle 3. For example, the charging monitoring apparatus 1 may be implemented as a server apparatus S communicably connected to the vehicle 3 over a communication network NW such as the Internet.

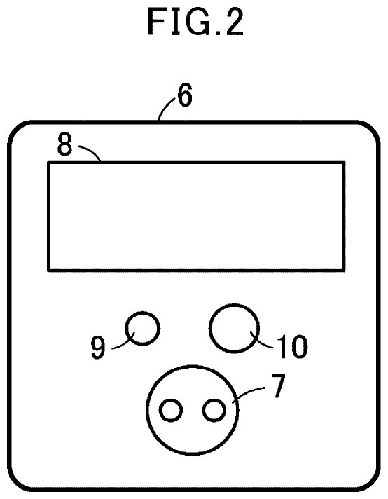

The vehicle 3 has a vehicle outer surface having a charging opening 6, and a power supply cable CA of the power supply device PS is connected to a charging connector 7 (FIG. 2) provided inside the charging opening 6 so that charging from the power supply device PS is performed. The charging opening 6 has a charging lid, not shown, according to a conventional technology and is closed by the charging lid when charging from the power supply device PS is not received.

A user U of the vehicle 3 may take a nap within the vehicle 3 or may leave the vehicle 3 with an FOB key 20 and/or a mobile terminal 21 being a vehicle key of the vehicle 3 for shopping or the like with him/her while charging is performed from the power supply device PS to the secondary battery 5. The mobile terminal 21 may include a touch panel 22 according to a conventional technology.

Here, the user U corresponds to a current user who is currently using the vehicle 3 according to the present disclosure. Furthermore, the mobile terminal 21 corresponds to a predefined user terminal device being accessible by the current user according to the present disclosure.

In the scene shown in FIG. 1, another person P who intends to charge from the power supply device PS to another vehicle V is waiting for completion of charging to the vehicle 3 outside the vehicle 3.

FIG. 2 is a diagram showing a configuration of an interior of the charging opening 6 of the vehicle 3. In addition to the charging connector 7, an external touch panel 8, an external microphone 9, and an external speaker 10 are arranged inside the charging opening 6. Here, the external touch panel 8 corresponds to an external display device arranged at a position viewable from outside of the vehicle 3 and an external input device operable by a person outside the vehicle 3 according to the present disclosure.

The external microphone 9 acquires voice of a person outside the vehicle 3. Furthermore, the external speaker 10 outputs voice toward outside of the vehicle 3.

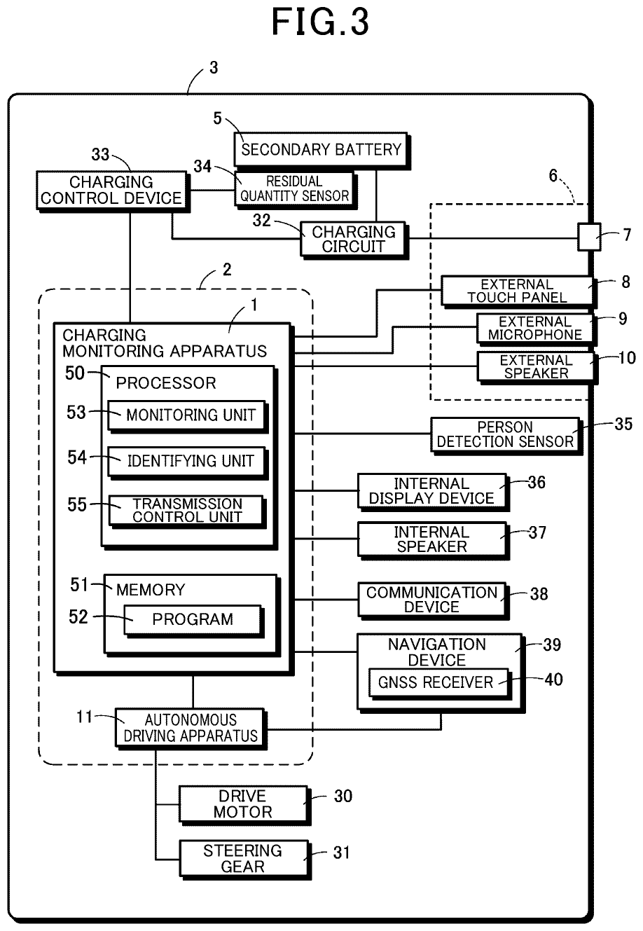

FIG. 3 is a diagram showing a configuration of the charging monitoring apparatus 1 and another apparatus included in the vehicle 3. The vehicle 3 includes an autonomous driving apparatus 11 that instructs a drive motor 30 that drives running of the vehicle 3 and a steering gear 31 that controls the direction of running of the vehicle 3 to cause the vehicle 3 to perform autonomous driving. The charging monitoring apparatus 1 is included in the charging monitoring system 2 along with the autonomous driving apparatus 11. The autonomous driving apparatus 11 causes the vehicle 3 to run to a predetermined destination defined in advance by autonomous driving when the charging monitoring apparatus 1 receives an allowance notification for autonomous driving. The autonomous driving apparatus 11 causes the vehicle 3 to be parked at the destination when it arrives at the destination.

The vehicle 3 includes a charging circuit 32 that controls power supply from the charging connector 7 to the secondary battery 5 and a charging control device 33 that includes a processor and that controls the charging circuit 32. The charging circuit 32 starts and ends the charging operation into the secondary battery 5 in accordance with an instruction from the charging control device 33. The charging circuit 32 measures a terminal voltage, a terminal current, and an inter-terminal impedance of the secondary battery 5 and transmits them to the charging control device 33 at predetermined time intervals while the secondary battery 5 is charged.

The charging control device 33 acquires information on the current residual capacity of the secondary battery 5 from a residual quantity sensor 34 at predetermined time intervals where the residual quantity sensor 34 detects a residual capacity (or a state of charge or SOC) of the secondary battery 5. The charging control device 33 transmits the acquired information on the current residual capacity of the secondary battery 5 to the charging monitoring apparatus 1 at predetermined time intervals.

The charging control device 33 receives power input via the charging connector 7 and, when the current residual capacity of the secondary battery 5 is lower than a predetermined value, instructs the charging circuit 32 to start the charging operation into the secondary battery 5. When the charging operation into the secondary battery 5 is started, the charging control device 33 transmits a charging start notification to the charging monitoring apparatus 1.

Furthermore, after the charging operation into the secondary battery 5 is started, the charging control device 33, at predetermined time intervals, calculates an expected completion time that is an expected time until the residual capacity of the secondary battery 5 reaches a target value and the charging operation completes based on information such as the current residual capacity of the secondary battery 5 acquired from the residual quantity sensor 34 and a terminal voltage, a terminal current, and an inter-terminal impedance of the secondary battery 5 received from the charging circuit 32 according to a conventional technology. The charging control device 33 transmits the calculated expected completion time to the charging monitoring apparatus 1 at predetermined time intervals. In this embodiment, the aforementioned target value may, for example, be determined by a transmission control unit 55 in the charging monitoring apparatus 1, which is described later and be transmitted to the charging control device 33.

Furthermore, when the current residual capacity of the secondary battery 5 acquired from the residual quantity sensor 34 exceeds the aforementioned target value, the charging control device 33 instructs the charging circuit 32 to end the charging operation into the secondary battery 5. When the charging operation into the secondary battery 5 ends, the charging control device 33 transmits a charging completion notification to the charging monitoring apparatus 1.

The vehicle 3 further includes a person detection sensor 35, an internal display device 36, an internal speaker 37, and a communication device 38.

The person detection sensor 35 detects a person around the vehicle 3 and a person inside the vehicle 3 and locates the position of the detected person. The person detection sensor 35 may be, for example, one or more radars, sonars, pyroelectric sensors or cameras provided outside or inside of the vehicle 3.

The internal display device 36 may be a touch panel or the like provided at a position that can be easily seen by a passenger inside the vehicle 3, for example, near the center of an instrument panel in a vehicle width direction. Furthermore, the internal speaker 37 may be one speaker provided at a position where a passenger inside the vehicle 3 can easily hear, or a plurality of speakers distributed inside the vehicle 3. Here, the internal display device 36 and the internal speaker 37 correspond to an output device provided inside the vehicle 3 according to the present disclosure.

The communication device 38 includes transmitter/receiver for communicating with an apparatus external to the vehicle 3, such as the mobile terminal 21 and the server apparatus S. The communication device 38 further includes a short-range transmitter/receiver for performing short-range communication in order to communicate with a vehicle key for the vehicle 3 owned by the user U. The vehicle key for the vehicle 3 is, for example, a FOB key or an electronic key such as a mobile phone storing a key code. Hereinafter, the vehicle key for the vehicle 3 to be communicated by the communication device 38 is also called an electronic key for the vehicle 3.

The short-range transmitter/receiver included in the communication device 38 attempts communication with the electronic key for the vehicle 3 and searches the electronic key around the vehicle 3 via a plurality of antennas (not shown) distributed in the vehicle 3. For example, the communication device 38 transmits a response request to the electronic key and receives a reception response from the electronic key via each of distributed antennas in accordance with a conventional technology. Then, the communication device 38 locates the position of the electronic key having transmitted the aforementioned reception response based on a reception radio wave intensity of the reception response in each of the antennas and the position of each of the antennas in the vehicle 3.

The vehicle 3 further includes a navigation device 39. The navigation device 39 includes a global navigation satellite system (GNSS) receiver 40. The navigation device 39 includes a processor and locates the current position of the vehicle 3 through the GNSS receiver 40 and, for example, guides a path to a destination input by the user U and outputs path information according to a conventional technology. Furthermore, the navigation device 39 may calculate an estimated required time for moving on foot from the current position of the user U designated by the charging monitoring apparatus 1 to the current position of the vehicle 3 and transmit it to the charging monitoring apparatus 1.

In the case above, the autonomous driving apparatus 11 and the charging control device 33 may be an electronic control unit (ECU) including a processor and a memory, respectively.

The charging monitoring apparatus 1 includes a processor 50 and a memory 51. The memory 51 is constituted of, for example, a volatile and/or nonvolatile semiconductor memory and/or a hard disk device or the like.

The processor 50 is a computer including a CPU or the like, for example. The processor 50 may be configured to have a ROM in which a program is written, a RAM for temporarily storing data, and so on. The processor 50 includes, as functional elements or functional units, a monitoring unit 53, an identifying unit 54, and the transmission control unit 55.

These functional elements included in the processor 50 are realized by execution by the processor 50 being a computer, for example, of a program 52 saved in the memory 51. It should be noted that the program 52 can be prestored in an arbitrary computer-readable storage medium. Alternatively, a part or all of the functional elements included in the processor 50 can be constituted of hardware each including one or more electronic circuit components.

The monitoring unit 53 monitors a state of a charging operation from the power supply device PS to the secondary battery 5. More specifically, the monitoring unit 53 communicates with the charging control device 33 to acquire information regarding a charging operation into the secondary battery 5 and monitors a state of the charging operation. For example, the monitoring unit 53 recognizes whether the secondary battery 5 is charged or not by receiving a charging start notification and a charging end notification from the charging control device 33. Furthermore, the monitoring unit 53 acquires the residual capacity of the secondary battery 5 and the expected completion time from the charging control device 33 at predetermined time intervals and monitors the current residual capacity of the secondary battery 5 and the expected completion time of the charging operation of the secondary battery 5 while being charged.

The identifying unit 54 detects and identifies a person around the vehicle 3 and a person inside the vehicle 3. More specifically, the identifying unit 54 receives sensor information from the person detection sensor 35, detects a person around the vehicle 3 and a person inside the vehicle 3 and locates the position of the detected person. Furthermore, when a person around the vehicle 3 and a person inside the vehicle 3 is detected based on the sensor information from the person detection sensor 35, the identifying unit 54 searches for the electronic key for the vehicle 3 and locates the position of the electronic key present around the vehicle 3 through the communication device 38.

Then, when the position of the person detected by the person detection sensor 35 and the position of the electronic key located by the communication device 38 are matched, the identifying unit 54 identifies the detected person as a user U. Here, in a case where there are a plurality of people carrying the electronic key for the vehicle 3, each of the people carrying the electronic key may be detected as a user U (that is, the current user).

Thus, the identifying unit 54 detects a person around the vehicle 3 and identifies whether the detected person is the user U or not. Similarly, the identifying unit 54 detects a person inside the vehicle 3 and identifies whether the detected person is the user U or not.

The transmission control unit 55 controls a display operation of the external touch panel 8 being a display device and acquires an input through the external touch panel 8 being an input device. As described above, the external touch panel 8 corresponds to an external display device arranged at a position viewable from outside of the vehicle 3 and an external input device operable by a person outside the vehicle 3 according to the present disclosure.

In this embodiment, in particular, the transmission control unit 55 displays on the external touch panel 8 a notification screen toward a person around the vehicle 3 when the charging operation from the power supply device PS to the secondary battery 5 is in progress and when the identifying unit 54 detects that a person who is different from the user U is present around the vehicle 3. The notification screen may display a message that prompts continuation of waiting such as “It will take little while” or “Just a moment please”, for example.

Here, the fact that the charging operation from the power supply device PS to the secondary battery 5 is in progress can be recognized by the monitoring unit 53 described above.

For example, in the scene in FIG. 1, when a person P waiting for charging to another vehicle V is approaching near the vehicle 3, the identifying unit 54 detects a person different from the user U present around the vehicle 3. The transmission control unit 55 displays on the external touch panel 8 a notification screen toward the person P around the vehicle 3 when the monitoring unit 53 is recognizing that the charging operation to the secondary battery 5 is in progress and when the identifying unit 54 detects that the person P who is different from the user U is present around the vehicle 3.

Thus, the person P may look at the message displayed on the external touch panel 8 arranged inside the charging opening 6 of the vehicle 3 and learn that the vehicle 3 is still charged and can recognize that waiting now for completion of the charging to the vehicle 3 still does not waste time. Therefore, the person P does not have to wait without knowing whether the vehicle 3 is being charged or not, and therefore, it may be possible to avoid a situation in which the person P gives up waiting and moves the other vehicle V to another charging site in vain. As a result, sequential charging to a plurality of vehicles in the power supply device PS can be smoothly performed.

When a person different from the user U stays around the vehicle 3 for a predetermined time defined in advance or longer based on results of the detection and identification of a person by the identifying unit 54, the transmission control unit 55 displays the notification screen above on the external touch panel 8.

Thus, since the notification screen can be displayed on the external touch panel 8 only when a person who is highly probable to be waiting for completion of a charging operation to the vehicle 3 is detected around the vehicle 3, wasteful power consumption of the external touch panel 8 can be suppressed without causing the external touch panel 8 to display a wasteful notification screen.

The transmission control unit 55 may include information regarding a charging operation from the power supply device PS to the secondary battery 5 on the notification screen to be displayed on the external touch panel 8.

For example, as an example of the information regarding a charging operation, a message such as “Charging has not completed”, “Charging is in progress” or the like may be included in the notification screen.

Thus, since the information regarding a charging operation in the vehicle 3 can be provided to a person waiting for completion of the charging to the vehicle 3 around the vehicle 3, the number of cases where the waiting person gives up the waiting can be reduced. Therefore, sequential charging to a plurality of vehicles in the power supply device can be more smoothly performed.

Here, upon start of a charging operation to the secondary battery 5, the transmission control unit 55 can set a target value for the residual capacity in the charging operation to the secondary battery 5 and transmit it to the charging control device 33. The target value above may be a predetermined value that is defined in advance. Alternatively, the target value above may be a residual capacity required for running to a destination currently set for the navigation device 39. The transmission control unit 55 may acquire a distance of a path to a currently set destination from the navigation device 39 and calculate a residual capacity required for running to the destination according to a conventional technology based on the acquired distance and predefined electricity consumption (amount of power consumption per unit distance).

In displaying the notification screen on the external touch panel 8, when the charging operation from the power supply device PS to the secondary battery 5 has a predetermined state that is defined in advance, the transmission control unit 55 may also display a message that inquires about the necessity of notification to a passenger of the vehicle 3 on the external touch panel 8. When a notification request being a request for the notification to a passenger of the vehicle 3 is input via the external touch panel 8, the transmission control unit 55 may transmit an input notification that the notification request is input to the mobile terminal 21 of the user U.

The predetermined state may be a state acquired by charging the secondary battery 5 until the residual capacity of the secondary battery 5 reaches a predefined target value and finishing the charging operation. Alternatively, the predetermined state may be a state acquired by interrupting the charging operation of the secondary battery 5 before the residual capacity of the secondary battery 5 reaches the target value. Such an interruption of the charging operation may be caused by an operation trouble of the power supply device PS or the like. Additionally or alternatively, the predetermined state may be a state the secondary battery 5 is charged to a value acquired by multiplying a target value of the residual capacity of the secondary battery 5 by a predetermined ratio (80%, for example). The predetermined state can be defined in advance.

Thus, a person waiting for completion of the charging around the vehicle 3 while being charged can actively request the notification to the user U upon completion of the charging operation into the vehicle 3 or immediately before the completion of the charging operation or upon interruption of the charging operation. Thus, the person waiting for completion of the charging can avoid waiting for a long time in vain for completion of the charging since the user U of the vehicle 3 does not notice the predetermined state such as completion of the charging operation. As a result, sequential charging to a plurality of vehicles in the power supply device PS can be more smoothly performed.

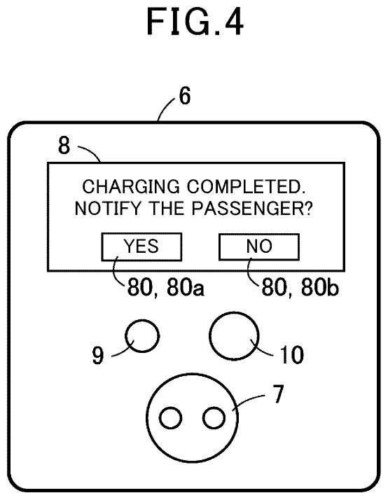

FIG. 4 shows an example of the notification screen including a message that is displayed on the external touch panel 8 and that inquires about necessity of a notification to a passenger of the vehicle 3. In the shown example, a state that the secondary battery 5 is charged up to the target value for the residual capacity is defined as the predetermined state. On the external touch panel 8 arranged in the charging opening 6, a message “Charging completed” indicating the predetermined state and a question message “Notify the passenger?” are displayed. Furthermore, a notification necessity button 80 is displayed under those messages which includes an affirmation button 80a displaying “YES” and a denial button 80b displaying “NO”.

It should be noted that the message indicating the predetermined state may be a message such as “Charging has been interrupted” or “Charging will end soon” in accordance with details of the predetermined state defined in advance, without limiting to “Charging has completed”.

When the person around the vehicle 3 (the person P in the scene shown in FIG. 1, for example) performs a touch operation on the affirmation button 80a, the transmission control unit 55 acquires the touch operation as the notification request and transmits the input notification to the mobile terminal 21 of the user U.

Furthermore, when the person around the vehicle 3 performs a touch operation on the denial button 80b, the transmission control unit 55 acquires the touch operation as an input and, for example, deletes the question message above, the affirmation button 80a, and the denial button 80b displayed on the external touch panel 8. In this case, after a lapse of a predetermined time, which is defined in advance, from the deletion, the transmission control unit 55 may again display the question message, the affirmation button 80a, and the denial button 80b above.

When a charging operation from the power supply device PS to the secondary battery 5 does not have the predetermined state, the transmission control unit 55 displays on the external touch panel 8 an expected time until the charging operation reaches the predetermined state or a current residual capacity of the secondary battery 5. For example, when the predetermined state is a state that the secondary battery 5 has been charged up to the target value of the residual capacity, the transmission control unit 55 displays on the external touch panel 8 the expected completion time of the charging operation. Such an indication may be a message “Charging has not been completed. Notification to passenger is allowed in 15 minutes”, for example. Here, “15 minutes” above may be the expected completion time for completion of the charging operation, which is calculated by the charging control device 33. Furthermore, “Notification to passenger is allowed in 15 minutes” above means that the notification screen including the message that inquires about necessity of the notification to the passenger of the vehicle 3 as shown in FIG. 4 will be displayed “in 15 minutes”.

Thus, since the person waiting for completion of the charging to the vehicle 3 around the vehicle 3 can learn the expected time up to achievement of the predetermined state such as completion of the charging, or the current residual capacity of the vehicle 3, the person can recognize an approximate length of the remaining waiting time. As a result, the number of cases where the waiting person gives up the waiting can further be reduced, and sequential charging to a plurality of vehicles in the power supply device PS can be more smoothly performed.

When the notification request above is input via the external touch panel 8, and when a passenger is detected inside the vehicle 3 by the identifying unit 54 (when the affirmation button 80a shown in FIG. 4 is touched, for example), the transmission control unit 55 may notify the passenger that there is a person waiting around the vehicle 3 through the internal display device 36 and/or the internal speaker 37 being an output device provided inside the vehicle 3. For example, the transmission control unit 55 may display a message such as “A person is waiting for completion of charging outside the vehicle” on the internal display device 36 and/or output a voice message from the internal speaker 37.

Thus, since the passenger inside the vehicle 3 while being charged can learn the existence of the person waiting for completion of the charging around the vehicle 3, the passenger can take a quick action toward movement of the vehicle 3 such as contacting the user U of the vehicle 3, moving the vehicle 3. Therefore, sequential charging to a plurality of vehicles in the power supply device PS can be more smoothly performed.

When the notification request above is input via the external touch panel 8 and when the user U is detected inside the vehicle 3 by the identifying unit 54, the transmission control unit 55 may notify the user U that there is a person waiting around the vehicle 3 through the internal display device 36 and/or the internal speaker 37. This notification may be, for example, display of a message such as “A person is waiting for completion of charging outside the vehicle” and/or voice output from the internal display device 36 or the internal speaker 37 as described above.

Since this allows the user U inside the vehicle 3 while being charged to recognize the existence of the person waiting for completion of the charging around the vehicle 3 and move the vehicle 3 quickly, sequential charging to a plurality of vehicles in the power supply device PS can be more smoothly performed.

When the notification request above is input via the external touch panel 8 and when the user U is not detected inside the vehicle 3 by the identifying unit 54, the transmission control unit 55 may transmit to the mobile terminal 21 of the user U a notification that there is a person waiting around the vehicle 3. The notification may be transmitted to the mobile terminal 21 as a push notification, for example. The mobile terminal 21 receives the notification above and displays the received notification on the touch panel 22 included in the mobile terminal 21 according to a conventional technology.

Thus, even when the user U of the vehicle 3 while being charged is away from the vehicle 3, when a person waiting for completion of the charging around the vehicle 3 recognizes the predetermined state such as a state that the charging of the vehicle 3 has completed, the person can actively notify the user U of the vehicle 3 of occurrence of the predetermined state relating to the charging operation. Therefore, the person waiting for completion of the charging can avoid waiting for a long time in vain for completion of the charging since the user U of the vehicle 3 does not notice the predetermined state even when the user U of the vehicle 3 while being charged is away from the vehicle 3. As a result, sequential charging to a plurality of vehicles in the power supply device can be smoothly performed even when the user U of the vehicle 3 while being charged is away from the vehicle 3.

When the notification request above is input via the external touch panel 8 and when the user U is not detected inside the vehicle 3 by the identifying unit 54, the transmission control unit 55 may establish communication with the mobile terminal 21 of the user U for talking via the external microphone 9 and the external speaker 10. The communication above may be a telephone communication through a public line with the mobile terminal 21, for example.

Thus, even when the user U of the vehicle 3 while being charged is away from the vehicle 3, a person waiting for completion of the charging around the vehicle 3 can talk with the user U and learn the condition of the user U. Thus, even when the user U of the vehicle while being charged is away from the vehicle 3, the person waiting for completion of charging can properly determine whether the waiting is to be continued or not from the situation of the user U of the vehicle acquired through the conversation, for example.

The transmission control unit 55 may also acquire an expected arrival time of the user U relative to the current charging location for the vehicle 3 (that is, the current position of the vehicle 3) input to the mobile terminal 21 by the user U and display the acquired expected arrival time on the external touch panel 8. For example, the transmission control unit 55 may display on the external touch panel 8 a message regarding the expected arrival time such as “The passenger will arrive in 10 minutes”. The transmission control unit 55 may display on the external touch panel 8 the message regarding the expected arrival time along with the message indicating the predetermined state.

Thus, even when the user U of the vehicle 3 while being charged is away from the vehicle 3, a person waiting for completion of the charging around the vehicle 3 can determine more properly whether the waiting is to be continued or not based on the expected arrival time.

For example, the user U can input the expected arrival time to the mobile terminal 21 in response to displaying, on the touch panel 22 of the mobile terminal 21, the notification that there is a person waiting around the vehicle 3, which is transmitted to the mobile terminal 21 by the transmission control unit 55. The mobile terminal 21 may acquire the input of the expected arrival time and transmit the input expected arrival time to the charging monitoring apparatus 1 in the vehicle 3 as one function of a predetermined application program, for example. When receiving the input notification described above as a push notification, for example, the mobile terminal 21 can display a message prompting to start the application program on the touch panel 22 and cause the user U to start the application program.

The transmission control unit 55 may also calculate an expected arrival time when the user U arrives at the vehicle 3 based on positional information on a current position of the user U transmitted by the mobile terminal 21 carried by the user U and a current position of the vehicle 3 acquired from the navigation device 39 and display the calculated expected arrival time on the external touch panel 8.

Thus, when the user U of the vehicle 3 while being charged is away from the vehicle 3 and even when the expected arrival time to the vehicle cannot be acquired from the user U, the expected arrival time can be calculated from a positional relationship between the user U and the vehicle 3 and be presented to a person around the vehicle 3 so that the person waiting for completion of the charging around the vehicle 3 can determine properly whether the waiting is to be continued or not based on the expected arrival time above.

For example, the transmission control unit 55 transmits, to the mobile terminal 21 running the application above, a request to transmit the current position. The mobile terminal 21 may respond to the transition request to transmit to the charging monitoring apparatus 1 the current position acquired from a GPS receiver (not shown) included in the mobile terminal 21 as a function of the application above.

When receiving an autonomous driving allowance notification from the mobile terminal 21 of the user U, the transmission control unit 55 transmits the received allowance notification to the autonomous driving apparatus 11. For example, the user U may be assumed to input an instruction to transmit, to the mobile terminal 21 running the application above, the autonomous driving allowance notification. The mobile terminal 21 transmits the autonomous driving allowance notification to the charging monitoring apparatus 1 in response to the input instruction to transmit as a function of the application according to a conventional technology.

In response to the transmission control unit 55 receiving the autonomous driving allowance notification and the monitoring unit 53 recognizing that the power supply cable CA is removed from the charging connector 7, the autonomous driving apparatus 11 can cause the vehicle 3 to run to a predetermined destination, which is defined in advance, by autonomous driving and cause the vehicle 3 to be parked in the destination. As the predetermined destination, it may be configured such that a plurality of destinations can be defined in advance. The autonomous driving apparatus 11 can cause the vehicle 3 to run by autonomous driving to a destination in a range that the vehicle 3 can run with the current residual capacity of the secondary battery 5 and cause the vehicle 3 to be parked at the destination. The transmission control unit 55 can acquire the current residual capacity of the secondary battery 5 from the monitoring unit 53 and transmit it along with the allowance notification above to the autonomous driving apparatus 11.

Thus, sequential charging to a plurality of vehicles in the power supply device PS can be smoothly performed because the vehicle 3 can be moved even when the user U of the vehicle 3 while being charged is far away from the vehicle 3 and cannot come back to the vehicle 3 quickly.

Next, a procedure of operations of the charging monitoring apparatus 1 is described.

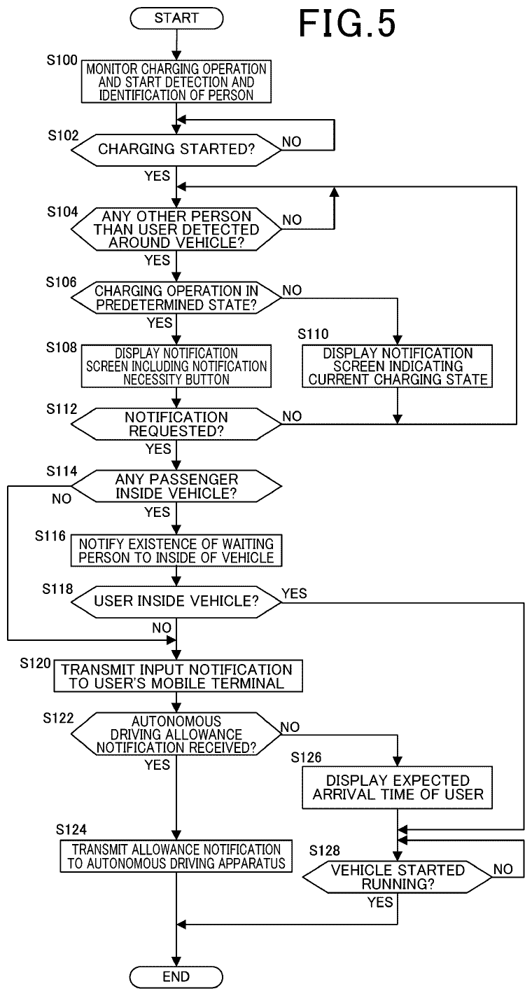

FIG. 5 is a diagram showing a procedure of processing in a charging start method to be executed by the processor 50 that is a computer of the charging monitoring apparatus 1. The processing shown in FIG. 5 starts when the activation of the charging monitoring apparatus 1 completes in a state that the power supply of each of the devices shown in FIG. 3 is turned on.

When the processing starts, the monitoring unit 53 in the charging monitoring apparatus 1 starts monitoring of a charging operation into the secondary battery 5, and the identifying unit 54 starts detection and identification of a person around and inside the vehicle 3 (S100). Next, the monitoring unit 53 determines whether charging into the secondary battery 5 has started or not (S102). When the charging into the secondary battery 5 has not started (S102, NO), the monitoring unit 53 returns to step S102 where the processing is repeated and waits until the charging into the secondary battery 5 is started.

When the charging into the secondary battery 5 has started (S102, YES), the identifying unit 54 determines whether a person other than the user U is detected around the vehicle 3 or not (S104). When a person other than the user U is not detected around the vehicle 3 (S104, NO), the identifying unit 54 returns to step S104 where the processing is repeated and waits for a person other than the user U being detected around the vehicle 3. At that time, when screen display is performed on the external touch panel 8, the transmission control unit 55 clears the display and exits the screen display.

On the other hand, when a person other than the user U is detected around the vehicle 3 (S104, YES), the transmission control unit 55 determines whether the charging operation into the secondary battery 5 has the aforementioned predetermined state or not based on information from the monitoring unit 53 (S106). Then, when the charging operation into the secondary battery 5 does not have the predetermined state (S106, NO), a notification screen indicating a current charging state is displayed on the external touch panel 8 (S110), and the processing then returns to step S104 and is repeated. As described above, the notification screen can include a message that prompts to continue waiting, a message that notifies information regarding the charging operation, and/or a message that indicates an expected time until the charging operation reaches the predetermined state or a residual capacity of the secondary battery 5, to a person around the vehicle 3.

On the other hand, when the charging operation into the secondary battery 5 has the predetermined state (S106, YES), the transmission control unit 55 displays the notification screen including the notification necessity button 80 on the external touch panel 8 (S108). The notification screen including the notification necessity button 80 may be a screen as shown in FIG. 4, for example.

Next, the transmission control unit 55 determines whether the notification request is received through the external touch panel 8 or not (S112). As described above, the notification request may be input by a person around the vehicle 3 by touching the affirmation button 80a of the notification necessity button 80 displayed on the external touch panel 8.

Then, when the notification request is not received (S112, NO), the transmission control unit 55 returns the processing to step S104. On the other hand, when the notification request is received (S112, YES), the transmission control unit 55 determines whether the identifying unit 54 detects a passenger inside the vehicle 3 or not (S114). When the identifying unit 54 detects a passenger inside the vehicle 3 (S114, YES), the transmission control unit 55 notifies the passenger that there is a person waiting around the vehicle 3 through the internal display device 36 and/or the internal speaker 37 inside the vehicle 3 (S116).

The transmission control unit 55 determines whether the identifying unit 54 detects the user U inside the vehicle 3 or not (S118). Then, when the identifying unit 54 does not detect the user U inside the vehicle 3 (S118, NO), the transmission control unit 55 transmits the input notification that the notification request has been input from a person around the vehicle 3 to the mobile terminal 21 of the user U (S120). On the other hand, the user U can transmit the autonomous driving allowance notification or the expected arrival time to the vehicle 3 to the charging monitoring apparatus 1 through the mobile terminal 21. For executing the step S120, the transmission control unit 55 further establishes talking communication with the mobile terminal 21 such that a person around the vehicle 3 can talk with the user U via the external microphone 9 and the external speaker 10.

Then, the transmission control unit 55 determines whether the autonomous driving allowance notification is received from the mobile terminal 21 of the user U or not (S122). When receiving the autonomous driving allowance notification from the mobile terminal 21 of the user U (S122, YES), the transmission control unit 55 transmits the received allowance notification to the autonomous driving apparatus (S124) and ends this processing. The autonomous driving apparatus 11 having received the allowance notification causes the vehicle 3 to perform autonomous driving to a predetermined destination and causes the vehicle 3 to be parked at the destination.

On the other hand, when the autonomous driving allowance notification is not received from the mobile terminal 21 of the user U in step S122 (S122, NO), the expected arrival time of the user U to the vehicle 3 received from the mobile terminal 21 of the user U or an expected arrival time calculated from the positional information on the mobile terminal 21 and the positional information on the vehicle 3 by the transmission control unit 55 are displayed on the external touch panel 8 (S126).

Next, the transmission control unit 55 determines whether the vehicle 3 has started running or not (S128). When the vehicle speed detected by a speed sensor (not shown) included in the vehicle 3 exceeds a predetermined value, the transmission control unit 55 can determine that the vehicle 3 has started running.

When the vehicle 3 does not start running (S128, NO), the transmission control unit 55 returns to step S128 where the processing is repeated and waits until the vehicle 3 starts running.

On the other hand, when the vehicle 3 has started running (S128, YES), the transmission control unit 55 ends the processing. After the end of the processing, the processor 50 in the charging monitoring apparatus 1 newly starts the processing and repeats the processing until the charging monitoring apparatus 1 is powered off.

On the other hand, when the identifying unit 54 detects the existence of the user U inside the vehicle 3 in step S118 (S118, YES), the transmission control unit 55 moves the processing to step S128.

Here, referring to FIG. 5, steps S100, S102, and S106 correspond to a monitoring step of the present disclosure. Furthermore, steps S100, S104, S114, and S118 correspond to an identifying step of the present disclosure. Furthermore, steps S108, S110, and S126 correspond to a transmitting step of the present disclosure.

### 2. Other Embodiments

Having described that the charging monitoring apparatus 1 in the aforementioned embodiment is included in the vehicle 3, but it may be configured as an external apparatus provided externally to the vehicle 3 as described above. For example, the charging monitoring apparatus 1 may be implemented as the server apparatus S communicably connected to the vehicle 3 over the communication network NW.

Having described that the identifying unit 54 detects the existence of the user U from the position of the electronic key for the vehicle 3 and the position of the person detected by the person detection sensor 35 in the aforementioned embodiment, the existence of the user U may be detected by recognizing a human facial image. For example, the person detection sensor 35 may include a camera that captures an image around the vehicle 3 and a camera that captures an image of inside of the vehicle 3, and the identifying unit 54 may compare a human facial image acquired from those cameras with a facial image of the user U prestored in the memory 51 in advance to detect the existence of the user U.

Furthermore, having described that the external touch panel 8 is arranged in the charging opening 6 in the aforementioned embodiment, it may be arranged at an arbitrary position that can be viewed from outside of the vehicle 3 and that is operable by a person outside the vehicle 3.

Furthermore, having described that the external display device and the external input device according to the present disclosure are implemented by the external touch panel 8 in the aforementioned embodiment, they may be implemented by a display device and an input device, respectively, that are separated from each other.

It should be noted that the present invention is not limited to the configurations of the aforementioned embodiments and can be implemented in various aspects without departing from the spirit and scope of the present invention.

### 3. Configurations Supported by the Aforementioned Embodiments

The aforementioned embodiments support the following configurations.

(Configuration 1) A charging monitoring apparatus, comprising a monitoring unit that monitors a state of a charging operation from a power supply device external to a vehicle to a secondary battery included in the vehicle, an identifying unit that detects and identifies a person around the vehicle, and a transmission control unit that controls an operation of an external display device, the external display device being a display device provided in the vehicle at a position viewable from outside of the vehicle, wherein the transmission control unit displays on the external display device a notification screen toward a person around the vehicle when the charging operation from the power supply device to the secondary battery is in progress and when it is detected that a person who is different from a current user, who is currently using the vehicle, is present around the vehicle.

According to the charging monitoring apparatus of Configuration 1, since, for example, a person waiting for completion of charging into one vehicle to charge another vehicle around the one vehicle can acquire information on a charging state and the like on the one vehicle through the notification screen displayed on the external display device of the one vehicle, it may be possible to avoid a situation in which such a person gives up waiting for charging into the one vehicle and moves the other vehicle to another charging site in vain, for example. As a result, sequential charging to a plurality of vehicles in the power supply device can be smoothly performed.

(Configuration 2) The charging monitoring apparatus according to Configuration 1, wherein, when a person different from the current user stays around the vehicle for a predetermined time defined in advance or longer, the transmission control unit displays the notification screen on the external display device.

According to the charging monitoring apparatus of Configuration 2, since the notification screen is displayed on the external display device when a person who is highly probable to be waiting for completion of a charging operation to the vehicle around the vehicle is detected, wasteful power consumption of the external display device can be suppressed without causing the external display device to display a wasteful notification screen.

(Configuration 3) The charging monitoring apparatus according to Configuration 1 or 2, wherein the notification screen includes information regarding a charging operation from the power supply device to the secondary battery.

According to the charging monitoring apparatus of Configuration 3, since the information regarding a charging operation in the vehicle can be provided to a person waiting for completion of the charging to the vehicle around the vehicle, the number of cases where the waiting person gives up the waiting can be reduced. Therefore, sequential charging to a plurality of vehicles in the power supply device can be more smoothly performed.

(Configuration 4) The charging monitoring apparatus according to any one of Configurations 1 to 3, wherein the transmission control unit acquires an input from an external input device provided in the vehicle, the external input device being operable by a person outside the vehicle, the transmission control unit displays on the external display device a message that inquires about necessity of a notification to a passenger of the vehicle when a charging operation from the power supply device to the secondary battery has a predetermined state defined in advance and, when a notification request is input via the external input device, transmits an input notification that the notification request is input to a user terminal device, the notification request being a request for the notification to a passenger of the vehicle, the user terminal device being defined in advance and being accessible by the current user.

According to the charging monitoring apparatus of Configuration 4, when a person waiting for completion of the charging to the vehicle around the vehicle recognizes the predetermined state such as a state that the charging of the vehicle has completed, the person can actively notify the user of the vehicle of occurrence of the predetermined state. Therefore, the person waiting for completion of the charging can avoid waiting for a long time in vain for completion of the charging since the user of the vehicle does not notice the predetermined state. As a result, according to the charging monitoring apparatus of Configuration 4, sequential charging to a plurality of vehicles in the power supply device can be more smoothly performed.

(Configuration 5) The charging monitoring apparatus according to Configuration 4, wherein, when a charging operation from the power supply device to the secondary battery does not have the predetermined state, the transmission control unit displays on the external display device an expected time until the charging operation reaches the predetermined state or a current residual capacity of the vehicle.

According to the charging monitoring apparatus of Configuration 5, since the person waiting for completion of the charging to the vehicle around the vehicle can learn the expected time up to achievement of the predetermined state such as completion of the charging or the current residual capacity of the vehicle above, the person can recognize an approximate length of the remaining waiting time. Thus, according to the charging monitoring apparatus of Configuration 5, the number of cases where the waiting person gives up the waiting can further be reduced, and sequential charging to a plurality of vehicles in the power supply device can be more smoothly performed.

(Configuration 6) The charging monitoring apparatus according to Configuration 4 or 5, wherein when the notification request is input via the external input device and when a passenger is detected inside the vehicle, the transmission control unit notifies the passenger that there is a person waiting around the vehicle through an output device provided inside the vehicle.

According to the charging monitoring apparatus of Configuration 6, since a passenger inside the vehicle while being charged can learn the existence of the person waiting for completion of the charging around the vehicle, the passenger can take a quick action toward movement of the vehicle such as contacting the user of the vehicle, moving the vehicle. Therefore, in the charging monitoring apparatus of Configuration 6, sequential charging to a plurality of vehicles in the power supply device can be more smoothly performed.

(Configuration 7) The charging monitoring apparatus according to Configuration 4 or 5, wherein the identifying unit identifies a person inside the vehicle, and, when the notification request is input via the external input device and when the current user of the vehicle is detected inside the vehicle, the transmission control unit notifies the current user that there is a person waiting around the vehicle through an output device provided inside the vehicle.

According to the charging monitoring apparatus of Configuration 7, since this allows a user of the vehicle inside the vehicle while being charged to recognize the existence of the person waiting for completion of the charging around the vehicle and move the vehicle quickly, sequential charging to a plurality of vehicles in the power supply device can be more smoothly performed.

(Configuration 8) The charging monitoring apparatus according to Configuration 7, wherein when the notification request is input via the external input device and when the current user is not detected inside the vehicle, the transmission control unit transmits a notification that there is a person waiting around the vehicle to a user terminal device, the user terminal device being defined in advance and being accessible by the current user.

According to the charging monitoring apparatus of Configuration 8, even when the user of the vehicle while being charged is away from the vehicle, when a person waiting for completion of the charging around the vehicle recognizes the predetermined state such as a state that the charging of the vehicle above has completed, the person can actively notify the user of the vehicle of occurrence of the predetermined state relating to the charging operation. Therefore, the person waiting for completion of the charging can avoid waiting for a long time in vain for completion of the charging since the user of the vehicle above does not notice the predetermined state even when the user of the vehicle while being charged is away from the vehicle. As a result, according to the charging monitoring apparatus of Configuration 8, sequential charging to a plurality of vehicles in the power supply device can be smoothly performed even when the user of the vehicle while being charged is away from the vehicle.

(Configuration 9) The charging monitoring apparatus according to Configuration 7 or 8, wherein the vehicle includes an external microphone that acquires voice of a person present outside the vehicle and an external speaker that outputs voice to outside of the vehicle, and, when the notification request is input via the external input device and when the current user is not detected inside the vehicle, the transmission control unit establishes communication with a predefined user terminal device owned by the current user for allowing talking by employing the external microphone and the external speaker.

According to the charging monitoring apparatus of Configuration 9, even when the user of the vehicle while being charged is away from the vehicle, a person waiting for completion of the charging around the vehicle can talk with the user and learn the condition of the user. Thus, even when the user of the vehicle while being charged is away from the vehicle, the person waiting for completion of the charging can properly determine whether the waiting is to be continued or not from the situation of the user of the vehicle acquired through the conversation, for example.

(Configuration 10) The charging monitoring apparatus according to Configuration 8 or 9, wherein the transmission control unit acquires an expected arrival time of the current user to a charging location for the vehicle, the expected arrival time being input to the user terminal device by the current user, and displays the acquired expected arrival time on the external display device.

According to the charging monitoring apparatus of Configuration 10, even when the user of the vehicle while being charged is away from the vehicle, a person waiting for completion of the charging around the vehicle can determine more properly whether the waiting is to be continued or not based on the expected arrival time.

(Configuration 11) The charging monitoring apparatus according to any one of Configurations 8 to 9, wherein the user terminal device is a mobile terminal carried by the current user, and the transmission control unit calculates an expected arrival time when the current user arrives at the vehicle based on positional information on a current position of the current user transmitted by the user terminal device and a current position of the vehicle and displays the calculated expected arrival time on the external display device.

According to the charging monitoring apparatus of Configuration 11, when the user of the vehicle while being charged is away from the vehicle and even when the expected arrival time to the vehicle cannot be acquired from the user, the expected arrival time can be calculated from a positional relationship between the user and the vehicle and be presented to a person around the vehicle so that the person waiting for completion of the charging around the vehicle can determine properly whether the waiting is to be continued or not based on the expected arrival time above.

(Configuration 12) The charging monitoring apparatus according to any one of Configurations 4 to 11, wherein the predetermined state is a state acquired by charging the secondary battery until the residual capacity of the secondary battery reaches a predefined target value and finishing the charging operation and/or a state acquired by interrupting the charging operation of the secondary battery before the residual capacity of the secondary battery reaches the target value.

According to the charging monitoring apparatus of Configuration 12, since a person waiting for completion of the charging around the vehicle while being charged can be notified upon completion or interruption of the charging operation into the vehicle, the person can properly determine whether the waiting is to be continued or not.

(Configuration 13) A charging monitoring system, comprising the charging monitoring apparatus according to any one of Configurations 1 to 12 and an autonomous driving apparatus being mounted in the vehicle and causing the vehicle to run to a destination by autonomous driving, wherein the transmission control unit in the charging monitoring apparatus communicates with a predefined user terminal device being accessible by the current user, and the autonomous driving apparatus causes the vehicle to run to a predetermined destination defined in advance by autonomous driving and causes the vehicle to be parked at the destination when the transmission control unit receives an allowance notification for autonomous driving from the user terminal device.

According to the charging monitoring system of Configuration 13, sequential charging to a plurality of vehicles in the power supply device can be smoothly performed because the vehicle can be moved even when the user of the vehicle while being charged is far away from the vehicle and cannot come back to the vehicle above quickly.

(Configuration 14) A charging monitoring method executed by a computer in a charging monitoring apparatus that monitors a charging operation from a power supply device external to a vehicle to a secondary battery included in the vehicle, the method comprising a monitoring step of monitoring a state of a charging operation from the power supply device to the secondary battery, an identifying step of detecting and identifying a person around the vehicle, and a transmitting step of controlling an operation of an external display device, the external display device being a display device provided in the vehicle at a position viewable from outside of the vehicle, wherein the transmitting step displays on the external display device a notification screen toward a person around the vehicle when the charging operation from the power supply device to the secondary battery is in progress and when it is detected that a person who is different from a current user, who is currently using the vehicle, is present around the vehicle.

According to the charging monitoring method of Configuration 14, since, for example, a person waiting for completion of charging into one vehicle to charge another vehicle around the one vehicle can acquire information on a charging state and the like on the one vehicle through the notification screen displayed on the external display device of the one vehicle, it may be possible to avoid a situation in which such a person gives up waiting for charging into the one vehicle and moves the other vehicle to another charging site in vain, for example. As a result, sequential charging to a plurality of vehicles in the power supply device can be smoothly performed.

### REFERENCE SIGNS LIST

1: charging monitoring apparatus, 2: charging monitoring system, 3: vehicle, 5: secondary battery, 6: charging opening, 7: charging connector, 8: external touch panel, 9: external microphone, 10: external speaker, 20: FOB key, 21: mobile terminal, 22: touch panel, 30: drive motor, 31: steering gear, 32: charging circuit, 33: charging control device, 34: residual quantity sensor, 35: person detection sensor, 36: internal display device, 37: internal speaker, 38: communication device, 39: navigation device, 40: GNSS receiver, 50: processor, 51: memory, 52: program, 53: monitoring unit, 54: identifying unit, 55: transmission control unit, 80: notification necessity button, 80a: affirmation button, 80b: denial button, NW: communication network, P: person, PS: power supply device, CA: charging cable, S: server apparatus, U: user, V: another vehicle

1. A charging monitoring apparatus, comprising:
a monitoring unit that monitors a state of a charging operation from a power supply device external to a vehicle to a secondary battery included in the vehicle;
an identifying unit that detects and identifies a person around the vehicle; and
a transmission control unit that controls an operation of an external display device, the external display device being a display device provided in the vehicle at a position viewable from outside of the vehicle,
wherein the transmission control unit displays on the external display device a notification screen toward a person around the vehicle when the charging operation from the power supply device to the secondary battery is in progress and when it is detected that a person who is different from a current user, who is currently using the vehicle, is present around the vehicle.

2. The charging monitoring apparatus according to claim 1, wherein, when a person different from the current user stays around the vehicle for a predetermined time defined in advance or longer, the transmission control unit displays the notification screen on the external display device.

3. The charging monitoring apparatus according to claim 1, wherein the notification screen includes information regarding a charging operation from the power supply device to the secondary battery.

4. The charging monitoring apparatus according to claim 1, wherein
the transmission control unit acquires an input from an external input device provided in the vehicle, the external input device being operable by a person outside the vehicle,
the transmission control unit displays on the external display device a message that inquires about necessity of a notification to a passenger of the vehicle when a charging operation from the power supply device to the secondary battery has a predetermined state defined in advance, and
when a notification request is input via the external input device, transmits an input notification that the notification request is input to a user terminal device, the notification request being a request for the notification to a passenger of the vehicle, the user terminal device being defined in advance and being accessible by the current user.

5. The charging monitoring apparatus according to claim 4, wherein when a charging operation from the power supply device to the secondary battery does not have the predetermined state, the transmission control unit displays on the external display device an expected time until the charging operation reaches the predetermined state or a current residual capacity of the vehicle.

6. The charging monitoring apparatus according to claim 4, wherein when the notification request is input via the external input device and when a passenger is detected inside the vehicle, the transmission control unit notifies the passenger that there is a person waiting around the vehicle through an output device provided inside the vehicle.

7. The charging monitoring apparatus according to claim 4, wherein
the identifying unit identifies a person inside the vehicle, and
when the notification request is input via the external input device and when the current user of the vehicle is detected inside the vehicle, the transmission control unit notifies the current user that there is a person waiting around the vehicle through an output device provided inside the vehicle.

8. The charging monitoring apparatus according to claim 7, wherein when the notification request is input via the external input device and when the current user is not detected inside the vehicle, the transmission control unit transmits a notification that there is a person waiting around the vehicle to a user terminal device, the user terminal device being defined in advance and being accessible by the current user.

9. The charging monitoring apparatus according to claim 7, wherein
the vehicle includes an external microphone that acquires voice of a person present outside the vehicle and an external speaker that outputs voice to outside of the vehicle, and
when the notification request is input via the external input device and when the current user is not detected inside the vehicle, the transmission control unit establishes communication with a predefined user terminal device owned by the current user for allowing talking by employing the external microphone and the external speaker.

10. The charging monitoring apparatus according to claim 8, wherein the transmission control unit acquires an expected arrival time of the current user to a charging location for the vehicle, the expected arrival time being input to the user terminal device by the current user, and displays the acquired expected arrival time on the external display device.

11. The charging monitoring apparatus according to claim 8, wherein
the user terminal device is a mobile terminal carried by the current user, and
the transmission control unit calculates an expected arrival time when the current user arrives at the vehicle based on positional information on a current position of the current user transmitted by the user terminal device and a current position of the vehicle and displays the calculated expected arrival time on the external display device.

12. The charging monitoring apparatus according to claim 4, wherein the predetermined state is a state acquired by charging the secondary battery until a residual capacity of the secondary battery reaches a predefined target value and finishing the charging operation and/or a state acquired by interrupting the charging operation of the secondary battery before the residual capacity of the secondary battery reaches the target value.

13. A charging monitoring system, comprising:
the charging monitoring apparatus according to claim 1; and
an autonomous driving apparatus being mounted in the vehicle and causing the vehicle to run to a destination by autonomous driving, wherein
the transmission control unit in the charging monitoring apparatus communicates with a predefined user terminal device being accessible by the current user, and
the autonomous driving apparatus causes the vehicle to run to a predetermined destination defined in advance by autonomous driving and causes the vehicle to be parked at the destination when the transmission control unit receives an allowance notification for autonomous driving from the user terminal device.

14. A charging monitoring method executed by a computer in a charging monitoring apparatus that monitors a charging operation from a power supply device external to a vehicle to a secondary battery included in the vehicle, the method comprising:
a monitoring step of monitoring a state of a charging operation from the power supply device to the secondary battery;
an identifying step of detecting and identifying a person around the vehicle; and
a transmitting step of controlling an operation of an external display device, the external display device being a display device provided in the vehicle at a position viewable from outside of the vehicle,
wherein the transmitting step displays on the external display device a notification screen toward a person around the vehicle when the charging operation from the power supply device to the secondary battery is in progress and when it is detected that a person who is different from a current user, who is currently using the vehicle, is present around the vehicle.
